(19) United States
(12) Patent Application Publication
(10) Pub. No.: US 2026/0305337 A1
(43) Pub. Date: Oct. 1, 2026

(54) INTEGRATED CIRCUIT PACKAGE

(71) Applicant: STMicroelectronics International N.V., Geneva (CH)

(72) Inventors: Asma HAJJI, Voiron (FR); Ouafa HAJJI, Voiron (FR); Fabien QUERCIA, Saint Marcellin (FR); Younes BOUTALEB, Grenoble (FR)

(73) Assignee: STMicroelectronics International N.V., Geneva (CH)

(21) Appl. No.: 19/629,545

(22) Filed: Mar. 26, 2026

(30) Foreign Application Priority Data
Mar. 27, 2025 (FR) FR2503140

(51) Int. Cl. H10W 40/20; H10W 74/10; H10W 74/47; H10W 76/01; H10W 74/15; H10W 90/00

(52) U.S. Cl. CPC H10W 40/242; H10W 74/141; H10W 74/47; H10W 76/01; H10W 74/15; H10W 90/724

(57) ABSTRACT

The manufacture of an electronic device includes a step a) of providing an assembly including a chip and an interconnection substrate, where the chip has a first surface with connection areas and a second surface, where the connection areas are assembled on the interconnection substrate by contact pads, and wherein the chip is encapsulated in a molding compound, for example an epoxy molding compound, that leaves the second surface of the chip accessible. A lid is assembling on the molding compound with a gap between the lid and the accessible second surface of the chip. A thermally-conductive resin is injected to fill the gap between the lid and the second surface of the chip.

### PRIORITY CLAIM

This application claims the priority benefit of French Application for Patent No. FR2503140, filed on Mar. 27, 2025, the content of which is hereby incorporated by reference in its entirety to the maximum extent allowable by law.

### TECHNICAL FIELD

The present disclosure generally concerns electronic components and, more particularly, integrated circuit packages (for example, packages of ball grid array (BGA) type) and the mounting of electronic chips in these packages.

### BACKGROUND

BGA-type packages enable to electrically integrate a chip to an external component, such as, for example, a printed circuit board (PCB).

With the miniaturization of electronic components, heat dissipation management is becoming more and more critical. To improve the thermal performance of electronic components, packages comprise a thermally-conductive lid (or cover) positioned over the chip. The lid supports the dissipation of heat generated by the chip.

The presence of a thermal interface material (TIM) positioned on the chip and in contact with the lid can facilitate heat dissipation.

The lid, when it has a hat like shape, can be directly attached to the substrate by means of glue. The heat dissipation is performed from the back side of the chip via the TIM layer.

There also exist BGA-type packages for which the chip, assembled to the substrate, is embedded in an epoxy molding compound (EMC) leaving the back side of the chip accessible. The thermal interface material (TIM) is then applied to the back side of the chip and to a portion of the EMC. The planar lid is then mounted on the TIM.

The TIM plays the role of both a heat sink and an adhesive. TIM generally has a thermal conductivity of at most 2W/m.K

There exists a need to improve packages for electronic chips, and in particular to a need improve the heat dissipation of these packages.

### SUMMARY

In an embodiment, a method of manufacturing an electronic device comprises the following steps: a) providing an assembly comprising an integrated circuit chip and an interconnection substrate, the chip having a first surface covered by connection areas and a second surface, the connection areas being assembled on the interconnection substrate by contact pads, the chip being molded in a molding compound, for example an epoxy molding compound, leaving the second surface of the chip accessible; b) assembling a lid over the assembly provided at step a), a gap being formed between the lid and the second surface of the chip; and c) injecting a thermally-conductive resin in such a way as to fill the gap between the lid and the second surface of the chip.

According to a specific embodiment, the thermally-conductive resin is an epoxy resin having thermally-conductive fillers, for example silica fillers, dispersed therein.

According to a specific embodiment, the thermally-conductive resin and the molding compound are made of a same material.

According to a specific embodiment, the lid is a plate and the lid is glued to the molding compound by means of glue dots or of a discontinuous glue bead.

According to a specific embodiment, the lid comprises a planar portion and elements projecting from the planar portion, the projecting elements being attached to the bottom of cavities formed in the molding compound.

According to a specific embodiment, the cavities have a thickness smaller than the thickness of the molding compound, and the protruding elements are glued to the molding compound forming the bottom of the cavities.

According to a specific embodiment, the cavities emerge onto the interconnection substrate, and the protruding elements are glued or soldered to the interconnection substrate.

According to a specific embodiment, the projecting elements form feet, for example four feet, or plates.

According to a specific embodiment, step c) is carried out by film-assisted molding.

In an embodiment, an electronic device comprises: an electronic integrated circuit chip arranged between an interconnection substrate and a lid, the chip having a first surface covered by connection areas and a second surface, the connection areas being assembled to the interconnection substrate by contact pads; the chip being molded in a molding compound, for example an epoxy molding compound, leaving the second surface of the chip accessible; a lid, preferably made of copper, covering the second surface of the chip; and a thermally-conductive resin filling the gap between the lid and the second surface of the chip, and preferably covering the flanks of the lid.

According to a specific embodiment, the thermally-conductive resin is an epoxy resin having thermally-conductive fillers dispersed therein.

According to a specific embodiment, the thermally-conductive resin is identical to the molding compound.

According to a specific embodiment, the lid is a plate and the lid is glued to the molding compound by means of glue dots or of a discontinuous glue bead.

According to a specific embodiment, the lid comprises a planar portion and elements projecting from the planar portion, the projecting elements being attached to the bottom of cavities formed in the molding compound.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIGS. 1A to 1C schematically show different steps of a method of manufacturing an integrated circuit package;

FIGS. 2A to 2C schematically show different steps of a method of manufacturing an integrated circuit package;

FIGS. 3A to 3C schematically show different steps of a method of manufacturing an integrated circuit package;

FIGS. 4A to 4C show, schematically and in three dimensions, different lids for integrated circuit packages according to different specific embodiments; and

FIGS. 5A to 5C show, schematically and in top view, a chip embedded in a molding compound on which glue has been deposited, according to different embodiments.

### DETAILED DESCRIPTION

In the various drawings, the different elements and components are not necessarily shown to the same scale as one another.

The same elements have been designated by the same The same elements have been designated by the same references in the various figures. In particular, structural and/or functional elements common to the different embodiments may have the same references and may have identical structural, dimensional and material properties.

For the sake of clarity, only those steps and elements that are useful for understanding the described embodiments have been shown and are described in detail.

Unless specified otherwise, when reference is made to elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as the terms "front", "back", "top", "bottom", "left", "right", etc., or relative position qualifiers, such as the terms "top", "bottom", "upper", "lower", etc., or orientation qualifiers, such as "horizontal", "vertical", etc., reference is made unless otherwise specified to the orientation of the drawings.

Unless specified otherwise, the expressions "about", "approximately", "substantially", and "in the order of" signify plus or minus 10% or 10°, preferably of plus or minus 5% or 5°.

By in the range from X to Y, there is meant that limits X and Y are included, which is equivalent to at least X and up to Y.

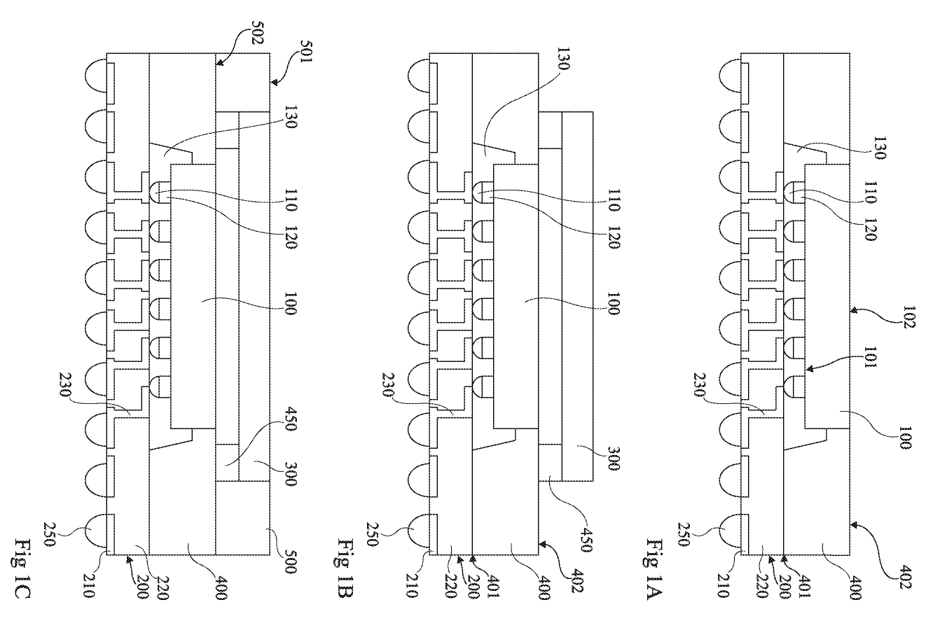

The method of manufacturing an integrated circuit package will now be described with reference to FIGS. 1A to 1C, 2A to 2C, and 3A to 3C.

The method comprises the following steps: a) providing an assembly comprising an integrated circuit chip 100 having a first surface 101 and a second surface 102 and an interconnection substrate 200, wherein the first surface 101 of chip 100 comprises interconnection areas 120, wherein the interconnection areas 120 are assembled on interconnection substrate 200 by contact pads 110, wherein the chip 100 is embedded in a molding compound 400, for example an epoxy molding compound, leaving the second surface 102 of chip 100 accessible (FIGS. 1A, 2A, and 3A); b) assembling a lid 300 on the assembly provided in step a), for example by bonding it to molding compound 400 or by bonding it or soldering it to interconnection substrate 200, wherein the lid 300 covers chip 100 with a gap being formed between lid 300 and the second surface 102 of chip 100 (FIGS. 1B, 2B, and 3B); and c) injecting a thermally-conductive resin 500 so as to fill the gap between lid 300 and the second surface 102 of chip 100, and preferably to cover the flanks of lid 300, wherein the thermally-conductive resin 500 is in contact with lid 300 and with the second surface 102 of chip 100 (FIGS. 1C, 2C, and 3C).

The thermally-conductive resin is a molded underfill material (MUF). A thermally-conductive resin is understood to mean a composite material comprising a resin (preferably an epoxy resin) and thermally-conductive fillers. Thermally-conductive fillers are, for example, inorganic fillers such as, without limitation, silica, aluminum nitride, zinc oxide, boron carbide, hexagonal boron nitride (h-BN), or aluminum nitride. The thermal conductivity of thermally-conductive resin 500 is, for example, greater than 2 W/m.K, preferably greater than 3 W/m.K, and even more preferably greater than 5 W/m.K. It may be as high as 7 W/m.K, for example.

The use of a thermally-conductive resin 500 of MUF type enables to improve heat dissipation by a factor of three as compared with the use of a thermal interface material (TIM).

Since the lid is assembled on molding compound 400 or on substrate 200, thermally-conductive resin 500 is in contact with the entire second surface 102 of chip 100, which further improves heat dissipation from chip 100 to the outside.

Glue 450 or solder joints 460 play the role of a shim and enable to correctly position lid 300 at the desired height relative to chip 100.

With such a method, the uniformity (thickness and surface area covered) of resin layer 500 between lid 300 and chip 100 is controlled. The bond line thickness (BLT) is easily controlled by adjusting the glue thickness. It is typically in the range from 50 to 100 µm.

The resulting electronic device offers a very good heat dissipation.

Lid 300, molding compound 400, thermally-conductive resin 500, and interconnection substrate 200 form the package of chip 100. Device thus has good mechanical strength and delamination problems are avoided. The lifetime as well as the performance of the component are improved.

The different steps of this method and the different elements used to obtain the electronic device will now be described in further detail.

The assembly provided at step a) comprises an integrated circuit chip 100 assembled on an interconnection substrate 300 by means of contact pads 110.

Chip 100 comprises a first main surface 101 (lower or front-side surface) and a second main surface 102 (upper or back-side surface). It also includes lateral surfaces coupling the main surfaces together.

Chip 100 may comprise a substrate, inside and/or on top of which are formed integrated circuits and/or discrete electronic elements, such as transistors, and an interconnection stack formed of insulating and conductive layers located on the side of the first surface 101 of chip 100. For example, the substrate is a semiconductor substrate, in particular made of silicon. These different elements/parts are not shown in the drawings for a better readability.

Chip 100 is a so-called flip-chip, that is, the active portion of chip 100 is arranged opposite interconnection substrate.

The first main surface 101 is covered by connection areas 120. The connection between chip 100 and interconnection substrate 200 is made via these areas 120. Chip 100 may comprise a plurality of connection areas 120. Chip 100 may comprise at least some ten connection areas 120, for example, at least some hundred connection areas 120. As an example, connection areas 120 are evenly distributed over the lower surface 101 of chip 100. They may be arranged in an array network.

Connection areas 120 are made of an electrically-conductive material. For example, connection areas 120 are made of a solderable material. Connection areas 120 are, for example, made of copper, silver, or tin, or of an alloy, for example based on tin and silver (SnAg).

Connection areas 120 are electrically connected to the interconnection substrate by connection pads 110. Connection pads 110 are, for example, made of a solderable material.

Interconnection substrate 200 enables to assemble chip 100 to an external device according to a so-called surface-mount technique.

Interconnection substrate 200 may have, in top view, a substantially square or rectangular shape. As an example, substrate 200 is, in top view, larger than chip 100. Substrate 200 may have dimensions in top view greater than 10 mm by 10 mm and smaller than 110 mm by 110 mm, for example in the order of 25 mm by 25 mm.

Substrate 200 comprises, for example, a stack 220 of different insulating layers and of different metal layers to form interconnects between the two main surfaces of substrate 200. Substrate 200 may comprise metal vias 230 which extend vertically in the orientation of the drawings.

In the different drawings and in the different embodiments, a single chip 100 is shown. However, it is possible to have a plurality of chips.

Additional passive electronic devices, not shown, such as, for example, resistors, inductors, and capacitors, may be mounted on substrate 200 around chip 100.

An electrically-insulating polymer layer 130 (referred to in the art as an underfill) is positioned under chip 100, between interconnection substrate 200 and the first surface 101 of chip 100. Polymer layer 120 encapsulates the connection pads 110 of the chip. This layer 130 enables to protect the mechanical integrity of pads 110 and protects them from oxidation. This coating layer 130 is, for example, an epoxy layer. It is injected after the transfer of chip 100 onto substrate 200 by capillary action.

Chip 100 is partially embedded in a molding compound 400, leaving its second surface 102 accessible (i.e., exposed at the back surface of the molding compound 400). The lateral surfaces of chip 100 are covered by the epoxy molding compound. Molding compound 400 covers interconnection substrate 200 and the portion of electrically-insulating polymer layer 130 that may protrude from chip 100.

Molding compound 400 may be formed by film-assisted molding.

Molding compound 400 is preferably an epoxy molding compound (EMC). Molding compound 400 comprises a polymer matrix, preferably epoxy, having fillers, in particular inorganic fillers, dispersed therein. The inorganic fillers are, for example, silica fillers. Molding compound 400 may also comprise additives to improve its mechanical and/or thermal properties. During step a), the material is polymerized and rigid and enables to improve the mechanical strength of the components with which it is in contact.

Preferably, epoxy molding compound 400 is a material having a good thermal conductivity, so as to also allow heat dissipation through the flanks of the chip. It may be made of the same material as thermally-conductive resin 500, or of a different material.

Molding compound 400 has a first surface 401 in contact with the interconnection substrate and a second surface 402 which will subsequently be covered by lid 300 and thermally-conductive resin 500.

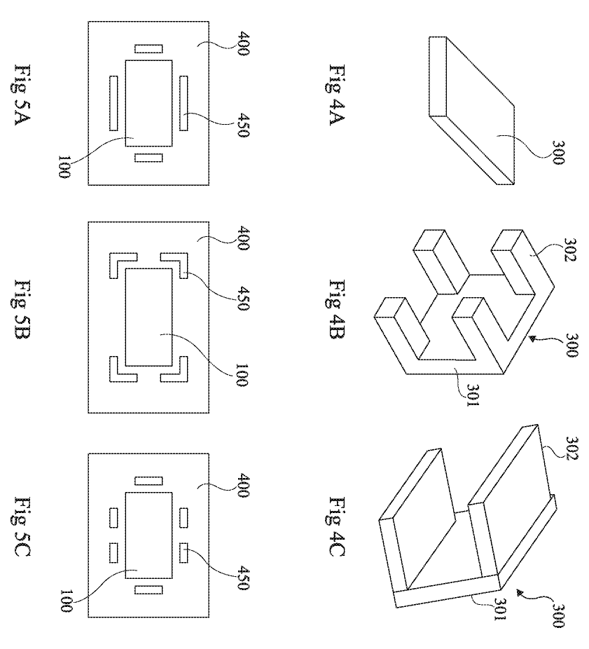

During step b), lid 300 is assembled to the assembly provided at step a). According to a specific embodiment, lid 300 may be planar (as for example shown in FIG. 4A). It may be a plate, for example. Lid 300 is glued to molding compound 400 by means of an adhesive 450 (as for example shown in FIG. 1B). Glue 450 may be deposited in the form of glue dots, a discontinuous glue bead, in a serpentine, 'X', or any other adapted pattern. Different glue patterns 450 are, for example, shown in FIGS. 5A to 5C. The shape of the glue pattern 450 and its thickness are selected, for example, according to the size of chip 100, in order to ensure a good bonding of lid 300 to molding compound 400 and to leave sufficient space for resin 500 to be injected under lid 300. The thickness of the glue pads, beads, or serpentines 450 is, for example, in the range from 50 to 100 µm.

According to another specific embodiment, lid 300 has a planar upper portion 301 intended to cover chip 100 and at least two lower elements 302 integral with upper portion 301 used to attach lid 300 to molding compound 400 or to substrate 200. The lower elements 302 are preferably perpendicular to upper portion 301. They form, for example, feet of the lid (FIG. 4B) or flat support elements (FIG. 4C). The flat support elements are plates, for example.

According to this embodiment, prior to step b), cavities, notches, or trenches may be formed in molding compound 400. In the following, cavities will be described, but any other non-through or through recess (depending on the embodiment) can be envisaged. Cavities 410 may be formed with a laser.

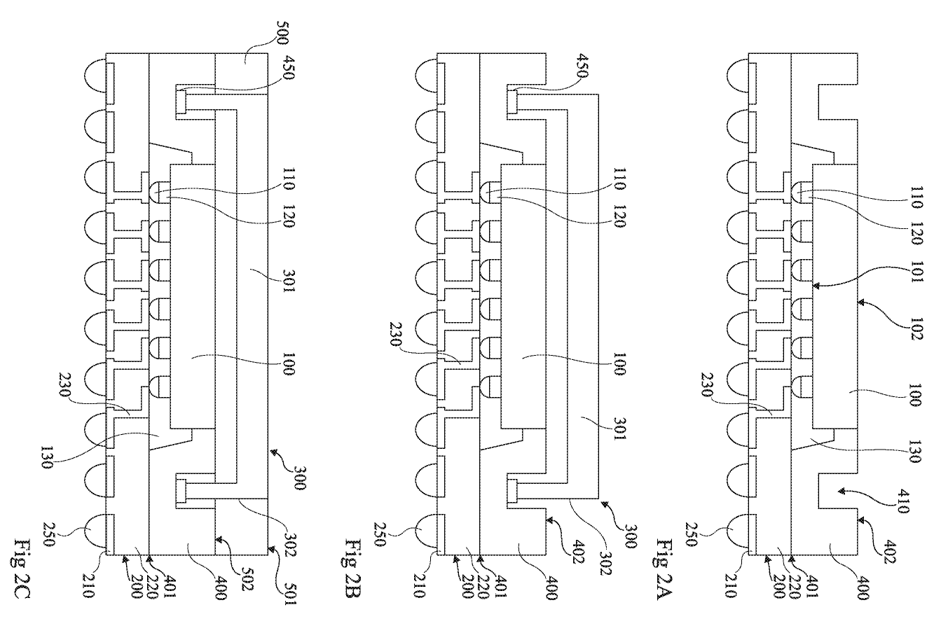

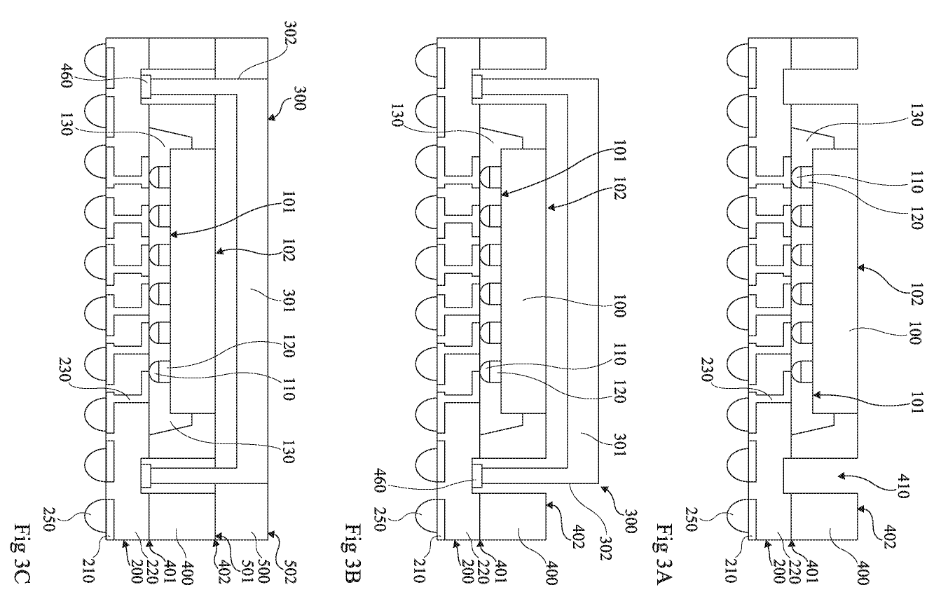

The dimensions of cavities 410 are selected according to the dimensions of lid 300. The lower elements 302 of the lid may be: glued to the bottom of cavities 410 on molding compound 400 when the cavities do not extend across the thickness of molding compound 400 (such as for example shown in FIG. 2B); or glued or soldered to the bottom of cavities 410, directly on interconnection substrate 200, by means of glue dots 450 or of solder joints 460 when cavities 410 extend across the thickness of molding compound 400 (as for example shown in FIG. 3B); for a soldering, interconnection substrate 200 will be configured to allow the soldering (for example, it will have locally on its surface at least one metal pad, or will be locally etched to make at least one metal layer present in the volume of stack 220 accessible).

According to these different embodiments, the shape of lid 300 and the positioning of glue 450/of solder joints 460 are selected in such a way that, at the end of step b), lid 300 covers chip 100, and so that it is possible to inject MUF 500 during step c). The resin 500 is injected into the space formed between the second surface 102 of chip 100 and lid 300.

According to these different alternative embodiments, glue 450 may be applied to lid 300 and/or to molding compound 400 (or to substrate 200).

A polymerization step may be carried out as a result of the deposition of glue 450.

Glue 450 is selected in such a way as to ensure a good mechanical resistance of lid 300 to the assembly provided at step a). Glue 450 is, for example, epoxy glue.

According to these different alternative embodiments, glue 450 does not cover chip 100. In the case of a planar lid 300, it will for example be chosen to position glue 450 at a distance of at least 500 µm from the edge of the second surface 102 of chip 100.

Lid 300 is thermally conductive. Lid 300 is, for example, a metal lid, for example, made of copper or of stainless steel, and is optionally plated with a nickel layer. The portion of lid 300 covering chip 100 has a thickness in the range from 300 to 1,000 µm, preferably from 500 to 1,000 µm.

During step c), thermally-conductive resin 500 is injected to form a heat dissipation layer between chip 100 and lid 300. Resin layer 500 enables to dissipate the heat generated by chip 100 during its operation towards metal lid 300 and then to the outside of device 1000.

Resin 500 is injected by molding. This type of material can infiltrate between lid 300 and molding compound 400 to fill the space between lid 300 and the second surface 102 of chip 100. Preferably, it also covers the flanks of lid 300.

Step c) is carried out in such a way as to leave the back side of lid 300 accessible (i.e., exposed at the back surface of resin 500). Resin 500 may be deposited by film-assisted molding injection.

Step c) may be carried out with equipment conventionally used in the microelectronics industry.

After injection of resin 500, a polymerization (curing) step is carried out. It may be carried out by thermal treatment, for example at a 175°C temperature for 3 hrs.

The cured resin 500 ensures a permanent and reliable thermal bond between lid 300 and chip 100.

Resin 500 thus acquires a certain rigidity and a certain adherence. It is thus not only integral with lid 300 and with chip 100, but also rigid. It may favor the mechanical hold of the final device.

Resin 500 is, for example, a suitable resin material as marketed by Sumitomo Bakelite Co, Ltd.

As a result of the method, an electronic component that can be assembled with an external element is obtained.

The electronic component comprises a chip 100 having a first surface 101 and a second surface 102, connection areas 120 positioned on the first surface 101 of chip 100 being assembled on a substrate 200 by connection pads 110.

A lid 300 made of a thermally-conductive material covers chip 100. It may be bonded either to molding compound 400 or to substrate 200 by gluing 400 or by soldering/brazing. Lid 300 is molded in a layer of thermally-conductive resin 500. Thermally-conductive resin 500 fills the space between lid 300 and the second surface 102 of chip 100, and extends to also cover the flanks of lid 300. Only the back side of the lid is not covered by resin 500.

Lid 300, molding compound 400, thermally-conductive resin 500, and interconnection substrate 200 form a package protecting chip 100 and enabling to electrically connect it to an external element (not shown in the drawings), for example an external device, or to a substrate of printed circuit board (PCB) type. Substrate 200 may be mounted and electrically connected to the external device, for example by means of interconnection pads 250 positioned on the second surface of substrate 200.

Interconnection pads 250 may be balls, pillars, or columns. Balls 250 are, for example, evenly distributed over the lower surface of substrate 200, for example in an array. The lateral dimensions of balls 250 and the pitch between balls 250 are, for example, respectively greater than the lateral dimensions of the contact pads 110 of the chip and are also greater than the pitch between pads 110 of chip 100. Substrate 200 thus performs a function of spreading and redistribution of the contacts of chip 100 towards the contacts of the external device.

Such electronic components, also known as a thermally enhanced flip-chip ball grid array (TEFCBGA) package or component, are particularly advantageous for a wide range of applications.

They enable to perform a large number of input/output (I/O) connections, with good a performance and a good heat dissipation.

The device is, for example, intended for the automotive industry. In particular, the device may be used in a microcontroller or in an advanced driver assistance system (ADAS).

It may be used in high-performance computing (HPC) devices, such as central processing units (CPUs) or in graphics processing units (GPUs).

The device may, for example, be used in the industrial field. More particularly, the device aims, for example, at being used for the development of green energies or for infrastructure electrification, for example for charging stations or for solar energy.

The device may also be used in the field of the Internet of Things and of smart homes.

The device may also be used in the implementation of 5G networks, data centers, and servers.

The device is, for example, intended to be used in personal electronics, for example to increase the radio frequency content, in 5G connection devices, or more generally in connected devices. The device is, for example, used in smart phones or for Internet-of-Things networks. The device is for example connected by 5G or WIFI. The device for example comprises high-speed interfaces, for example with an advanced filtering and a protection against electromagnetic discharges.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. A method of manufacturing an electronic device, comprising the following steps:
a) providing an assembly comprising an integrated circuit chip and an interconnection substrate, wherein the integrated circuit chip has a first surface covered by connection areas and a second surface, wherein the connection areas are assembled on the interconnection substrate by contact pads, and wherein the integrated circuit chip is encapsulated in a molding compound which leaves the second surface of the integrated circuit chip accessible;
b) assembling a lid on the assembly provided at step a), wherein there is a gap between the lid and the accessible second surface of the integrated circuit chip; and
c) injecting a thermally-conductive resin to fill the gap between the lid and the accessible second surface of the integrated circuit chip.

2. The method according to claim 1, wherein the molding compound is an epoxy molding compound.

3. The method according to claim 1, wherein the thermally-conductive resin is an epoxy resin having thermally-conductive fillers dispersed therein.

4. The method according to claim 3, wherein the thermally-conductive fillers are silica fillers.

5. The method according to claim 1, wherein the thermally-conductive resin and the molding compound are made of a same material.

6. The method according to claim 1, wherein the lid is a plate and wherein the lid is glued to the molding compound.

7. The method according to claim 1, wherein the molding compound includes cavities with bottoms, wherein the lid comprises a planar portion and elements projecting from the planar portion, and wherein the projecting elements are attached to the bottoms of the cavities.

8. The method according to claim 7, wherein the cavities have a thickness smaller than a thickness of the molding compound and wherein the projecting elements are glued to the bottom of the cavities.

9. The method according to claim 7, wherein the cavities emerge onto a surface of the interconnection substrate, and wherein the projecting elements are mounted to the surface of the interconnection substrate.

10. The method according to claim 7, wherein the projecting elements form one of: feet or plates.

11. The method according to claim 1, wherein step c) is carried out by film-assisted molding.

12. An electronic device, comprising:
an interconnection substrate;
an integrated circuit chip having a first surface covered by connection areas and a second surface, wherein the connection areas are mounted to the interconnection substrate by contact pads;
a molding compound encapsulating the integrated circuit chip, wherein the second surface of the integrated circuit chip is exposed at a back surface of the molding compound;
a lid covering the second surface of the integrated circuit chip; and
a thermally-conductive resin filling a space between the lid and the second surface of the integrated circuit chip.

13. The device according to claim 12, wherein thermally-conductive resin covers flanks of the lid.

14. The device according to claim 12, wherein the thermally-conductive resin is an epoxy resin having thermally-conductive fillers dispersed therein.

15. The device according to claim 14, wherein the thermally-conductive fillers are silica fillers.

16. The device according to claim 12, wherein the thermally-conductive resin is identical to the molding compound.

17. The device according to claim 12, wherein the lid is a plate and wherein the lid is glued to the back surface of the molding compound.

18. The device according to claim 12, wherein the molding compound includes cavities with bottoms, wherein the lid comprises a planar portion and elements projecting from the planar portion, and wherein the projecting elements are fastened to the bottom of cavities.

19. The device according to claim 18, wherein the cavities emerge onto a surface of the interconnection substrate, and wherein the projecting elements are mounted to the surface of the interconnection substrate.

20. The device according to claim 12, wherein the molding compound is an epoxy molding compound.
